(19) United States
(12) Patent Application Publication
(10) Pub. No.: US 2004/0219701 A1
(43) Pub. Date: Nov. 4, 2004

(54) Production of waveguides

(76) Inventors: Patrick Vincent Kelly, Cork (IE); Shane Anthony O'Brien, County Cork (IE)

Correspondence Address: JACOBSON HOLMAN, PROFESSIONAL LIMITED LIABILITY COMPANY, 400 SEVENTH STREET, N.W., WASHINGTON, DC, 20004, US

(21) Appl. No.: 10/859,086

(22) Filed: Jun. 3, 2004

Related U.S. Application Data
(63) Continuation of application No. PCT/IE02/00166, filed on Dec. 6, 2002.

(30) Foreign Application Priority Data
Dec. 6, 2001 (IE) 2001/1043

(51) Int. Cl. H01L 21/00

(52) U.S. Cl. 438/31; 430/321

(57) ABSTRACT

A planar waveguide (1) comprises a guiding layer (4) with densified cores (4, 5) for propagation of radiation. The cores (4, 5) are formed by selectively exposing the guiding layer (4) to UV at 222 nm with an intensity of 75 mW/cm?2 [symbol] at the surface. The guiding layer material comprises components in the methacrylate functional group. There is no need for use of photo-initiator additives in the guiding layer material.

### INTRODUCTION

1. Field of the Invention

The invention relates to production of waveguides, particularly multi-layer planar waveguides. Such waveguides may be used in production of passive components such as deflectors, wavelength filters, couplers, and mode converters.

2. Prior Art Discussion

In the area of sol-gel derived waveguide fabrication there are currently two main production methods, namely (a) a process which involves deposition, etching and patterning to produce the guiding regions and subsequent deposition of a cladding layer, and (b) a photopatterning or lithography approach.

The method (a) involving patterning and etching, while reasonably effective, is also very labour intensive and time-consuming, as a large number of steps are required for processing. It is for this reason that much current research is concerned with photopatterning or even photolithographic writing of waveguiding channels into sol-gel films or monoliths, which are made photosensitive by the addition of photoinitiators or photosensitisers to the sol-gel reaction mixture.

Use of photoinitiators in conjunction with sol-gel processing has been described by Popall, Schulz and Schmidt in U.S. Pat. No. 5,360,834, a process for photoinitiated control of inorganic network formation using sol-gel materials. In 1996, such technology was used by Coudray et al to produce waveguides by photopatterning methods in a methacrylate functionalised silica-zirconia sol-gel system [2]. The sol-gel glass material employed was synthesised by hydrolysis-polycondensation of methacryloxypropyl trimethoxysilane (MAPTMS), methacrylic acid and zirconium isopropoxide. HCl solution was added as a catalyst and Irgacure 184 (CIBA) was included as a photoinitiator. Deposited sol-gel materials were baked at 90° C. for 30 minutes, exposed to UV radiation through a mask for 4 hours and finally post-baked at 100° C. for 1 hour. The exposed areas undergo densification and an increase in refractive index results, thereby forming the guiding region of the waveguide.

In this process, it appears that photo-polymerisation and densification only occur to a depth of approximately 3.5 μm.

This group has also published work relating to the production of erbium doped acrylate functionalised silica waveguides [3]. This employs similar methods and principles as used in the MAPTMS prior art described above. A difference is the use of another sol-gel precursor, but which has similar chemical properties and chemical reactivity to MAPTMS.

A problem with the prior art approaches to formation of a waveguide by exposure of a sol-gel guiding layer to UV light has been the requirement for a photoinitiator. This has tended to cause the exposed guiding layer to swell and/or become fragile. They are thus not suitable for subsequent application of a cladding layer with a desired consistent interface. Where the cladding layer is in place before exposure, the interface between the guiding layer and the cladding layer may be damaged.

In more detail, a problem with this existing technology is that when used to produce planar, multi-layer devices, such as three-layer devices consisting of buffer, guiding and cladding layers, un-reacted photoinitiator material resides within part of the waveguide cladding (i.e.—photoinitiator remains in the regions of guiding layer that have not been exposed to UV radiation). This photoinitiator, which is by nature an unstable chemical species, may undergo thermal decomposition, for example during subsequent device processing, resulting in cross-linking and densification of portions of the cladding. Such behaviour would result in the loss of the refractive index difference between the core and cladding materials that is necessary for waveguiding to take place.

Another disadvantage of the use of photo-initiators in sol-gels is that portions of the sol-gel that are exposed to light bloat or swell and become brittle. The deformed material may also contain voids, which would greatly increase the optical losses of the guiding core material.

The invention addresses this problem.

References:

[1] M. Popall, J. Schultz, H.Schmidt, U.S. Patent 1994, U.S. Pat. No. 5,360,834

[2] P. Coudray, J. Chisham, A. Malek Tabrizi, Optics Communications, 128 (1996)1

[3] P. Etienne, P. Coudray, J. Porque, Y. Moreau, Optics Communications, 174 (2000) 413

### SUMMARY OF THE INVENTION

According to the invention, there is provided a method of producing a planar waveguide comprising the steps of selectively treating parts of a guiding layer to form a densified core in the guiding layer for propagation of radiation, wherein:

the guiding layer is treated by exposure to photo-patterning radiation, and

the guiding layer material and the photo-patterning radiation are chosen such that the core is densified without requirement for a photo-initiator additive in the guiding layer material.

In one embodiment, the photo-patterning radiation is generated by an excimer lamp.

In another embodiment, the photo-patterning radiation has a wavelength in the range of 172 nm to 308 nm.

In a further embodiment, the wavelength is in the range of 172 nm to 254 nm.

In one embodiment, the wavelength is approximately 222 nm.

In another embodiment, the photo-patterning radiation intensity is in the range 10 mW/cm² to 100 mW/cm² at the guiding layer exposed surface.

In a further embodiment, the intensity is in the range of 50 mW/cm² to 80 mW/cm² at the guiding layer exposed surface.

In one embodiment, the intensity is approximately 75 mW/cm².

In another embodiment, the guiding layer material comprises components in the acrylate functional group.

In a further embodiment, the guiding layer material comprises components in the methacrylate functional group.

In one embodiment, the guiding layer material comprises methacryloxymethyltriethoxysilate hydrolysed with dilute HCl.

In another embodiment, the guiding layer also comprises zirconium isopropoxide as a refractive index modifier, the volume being chosen according to the target refractive index.

In a further embodiment, the zirconium isopropoxide is reacted with methacrylic acid.

In one embodiment, the method comprises the further steps of depositing a buffer layer on a substrate, and subsequently depositing the guiding layer on the buffer layer.

In another embodiment, the guiding layer is treated after deposition on the buffer layer.

In a further embodiment, the method comprises the further step of depositing a cladding layer over the guiding layer.

In one embodiment, the cladding layer is deposited after treatment of the guiding layer.

In another embodiment, the buffer layer material is prepared by mixing Methyltrimethoxysilane (MTMOS) and Tetraethoxysilane (TEOS).

In a further embodiment, the method comprises the further step of adding dilute HCL as a condensation catalyst, and adding Diphenyl-dimethoxysilane (DPDMS) as a refractive index modifier to tune the refractive index of the buffer layer to a desired value.

In one embodiment, the guiding layer material is prepared in the same manner as the buffer layer material.

### DETAILED DESCRIPTION OF THE INVENTION

### BRIEF DESCRIPTION OF THE DRAWINGS

The invention will be more clearly understood from the following description of some embodiments thereof, given by way of example only with reference to the accompanying drawings in which:

FIG. 1 is a diagrammatic cross-sectional view of a waveguide; and

FIG. 2 is a flow diagram illustrating a waveguide production method of the invention.

### DESCRIPTION OF THE EMBODIMENTS

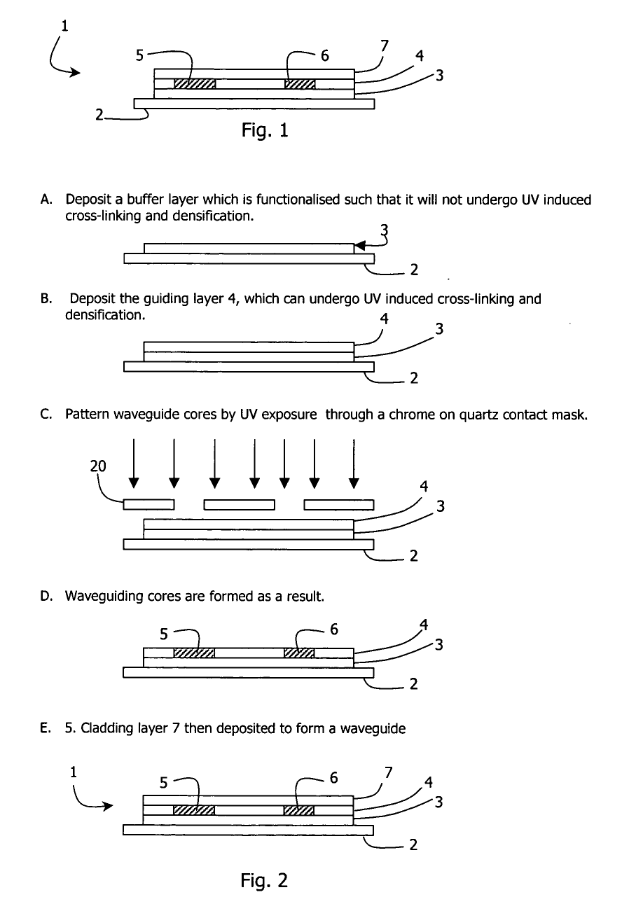

Referring to FIG. 1 a planar waveguide 1 is formed on a Silicon wafer substrate 2. The waveguide 1 comprises a buffer layer 3 applied directly over the substrate 2. A guiding layer 4 is applied over the buffer layer 3, and it comprises two guiding cores 5 and 6 for transmission of radiation. The cores 5 and 6 are formed by selective crosslinking and densification of sol-gel material of the guiding layer 4, the core material having a greater refractive index then the surrounding material. Finally, the waveguide 1 comprises a cladding layer 7 over the guiding layer 4.

In use, radiation of a desired wavelength is propagated through the cores 5 and 6 by total internal reflection arising from the interfaces between the cores 5 and 6 and the surrounding layers 3 and 7 and non-densified guiding layer sol-gel.

The layer thicknesses are:

buffer layer: 7 microns

guiding layer: 20 microns

cladding layer: 7 microns

Both the buffer and cladding layers are of a composition that does not contain functional groups which may undergo photo-induced condensation reactions, that would result in cross-linking, densification and an increase in refractive index.

The buffer and cladding layers are of the same material, prepared as follows:

Methyltrimethoxysilane (MTMOS) and Tetraethoxysilane (TEOS) are mixed (ratio 2:1) and stirred for 1 hour. Dilute HCl is then added as a condensation catalyst. Diphenyl-dimethoxysilane (DPDMS) is added as a refractive index modifier. The DPDMS content can be varied, resulting in a buffer/cladding material of tunable refractive index.

The guiding layer 4 material composition is prepared as follows:

Methacryloxymethyltriethoxysilane is hydrolysed with dilute HCl. Zirconium isopropoxide (refractive index modifier) is reacted with methacrylic acid in a separate container. As with the buffer/cladding layer sol-gel mixture, the zirconium content of the gel can be varied to yield a guiding layer material of tunable refractive index. The two solutions are then mixed and stirred for 1 hour. Water is then added and the mixture is stirred for 1 hour. The thickness can be set as desired by choice of number of depositions of the sol-gel.

Referring to FIG. 2, to fabricate the waveguide 1, the buffer layer sol-gel material is spin or dip coated in step A onto the substrate 2. It is then dried in an oven at 90° C. for 1 hour.

The guiding layer 4 material is then deposited and dried at 100° C. for 1 hour in step B. The guiding layer material contains components with functional groups which can undergo photo-induced condensation reactions resulting in cross-linking and densification. These functional groups are in this embodiment methacrylate groups.

Alternatively, acrylate groups may be used. When dry, a chrome on quartz photo-lithography mask 20 is placed on the sample in step C and in step D the exposed areas of the guiding layer 4 are exposed to intense excimer-lamp output at a wavelength of 222 nm and intensity of 75 mW/cm² on the sample surface.

The cladding layer 7 is then deposited in step E. This acts as the upper cladding layer of the waveguide—i.e. it prevents light leakage from the top of the waveguide. The cladding layer 7 is then dried at 100° C. for 2 hours.

Regarding choice of optical parameter values, the following are the preferred ranges:

Lamp wavelength: 172 to 308 nm, most preferably 172-254 nm, and Lamp intensity: 10 mW/cm² to 100 mW/cm², and most preferably 50-80 mW/cm² at the sample surface.

It is also possible to pattern guiding cores through the cladding layer, using high power excimer lamp radiation at 222 nm, to produce a waveguide, since the cladding and buffer layers will not undergo light-induced densification and refractive index changes.

It has been found that use of a narrow frequency range (or better still a single frequency such as 222 nm) and a high intensity achieve the required core densification in the guiding layer material. This avoids the need for photo-initiator additives.

More particularly, it has been demonstrated, that it is possible to achieve densification and a corresponding increase in refractive index (Δn) in methacrylate functionalised sol-gel materials by using high power excimer-lamp radiation at 222 nm in the absence of photoinitiator additives in the sol-gel system. In one representative experiment, Δn=0.0077 was obtained after 5 minutes of irradiation at 222 nm within an intensity of 75 mW/cm². Such a change in refractive index meets the requirements of both single and multi-mode waveguide fabrication.

It will be appreciated that because additives are not used in the guiding layer formulation, the prior problem of unconsumed unstable photo-initiator materials remaining in the cladding portion of the waveguide does not arise. Also, the invention avoids the problem of sol-gel materials containing photo-initiator additives swelling when exposed to light. Such swelled material would be brittle and fragment in contact with solvent or other sol-gel material.

Therefore, the stability of material properties of the sol-gel waveguide is greatly enhanced. The device produced by this method will be more robust and will consequently have a much longer working lifetime than multi-layer planar waveguides produced by prior art methods.

The invention is not limited to the embodiments described but may be varied in construction and detail.

1. A method of producing a planar waveguide comprising the steps of selectively treating parts of a guiding layer to form a densified core in the guiding layer for propagation of radiation, wherein:
the guiding layer is treated by exposure to photo-patterning radiation, and
the guiding layer material and the photo-patterning radiation are chosen such that the core is densified without requirement for a photo-initiator additive in the guiding layer material.

2. A method as claimed in claim 1, wherein the photo-patterning radiation is generated by an excimer lamp.

3. A method as claimed in claim 1, wherein the photo-patterning radiation has a wavelength in the range of 172 nm to 308 nm.

4. A method as claimed in claim 3, wherein the wavelength is in the range of 172 nm to 254 nm.

5. A method as claimed in claim 4, wherein the wavelength is approximately 222 nm.

6. A method as claimed in claim 1, wherein the photo-patterning radiation intensity is in the range 10 mW/cm² to 100 mW/cm² at the guiding layer exposed surface.

7. A method as claimed in claim 6, wherein the intensity is in the range of 50 mW/cm² to 80 mW/cm² at the guiding layer exposed surface.

8. A method as claimed in claim 7, wherein the intensity is approximately 75 mW/cm².

9. A method as claimed in claim 1, wherein the guiding layer material comprises components in the acrylate functional group.

10. A method as claimed in claim 1, wherein the guiding layer material comprises components in the methacrylate functional group.

11. A method as claimed in claim 10, wherein the guiding layer material comprises methacryloxymethyltriethoxysilate hydrolysed with dilute HCl.

12. A method as claimed in claim 11, wherein the guiding layer also comprises zirconium isopropoxide as a refractive index modifier, the volume being chosen according to the target refractive index.

13. A method as claimed in claim 12, wherein the zirconium isopropoxide is reacted with methacrylic acid.

14. A method as claimed in claim 1, comprising the further steps of depositing a buffer layer on a substrate, and subsequently depositing the guiding layer on the buffer layer.

15. A method as claimed in claim 14, wherein the guiding layer is treated after deposition on the buffer layer.

16. A method as claimed in claim 14, comprising the further step of depositing a cladding layer over the guiding layer.

17. A method as claimed in claim 16, wherein the cladding layer is deposited after treatment of the guiding layer.

18. A method as claimed in claim 14, wherein the buffer layer material is prepared by mixing Methyltrimethoxysilane (MTMOS) and Tetraethoxysilane (TEOS).

19. A method as claimed in claim 18, comprising the further step of adding dilute HCL as a condensation catalyst, and adding Diphenyl-dimethoxysilane (DPDMS) as a refractive index modifier to tune the refractive index of the buffer layer to a desired value.

20. A method as claimed in claim 18, wherein the guiding layer material is prepared in the same manner as the buffer layer material.
